(19) United States
(12) Patent Application Publication
(10) Pub. No.: US 2025/0392301 A1
(43) Pub. Date: Dec. 25, 2025

(54) DRIVING DEVICE FOR SWITCHING ELEMENT

(71) Applicant: KABUSHIKI KAISHA TOYOTA JIDOSHOKKI, Aichi (JP)

(72) Inventor: Yasushi NAKAMURA, Aichi (JP)

(73) Assignee: KABUSHIKI KAISHA TOYOTA JIDOSHOKKI, Aichi (JP)

(21) Appl. No.: 19/237,650

(22) Filed: Jun. 13, 2025

(30) Foreign Application Priority Data
Jun. 19, 2024 (JP) 2024-098898

(51) Int. Cl. H03K 17/082

(52) U.S. Cl. CPC H03K 17/0822; H03K 17/16

(57) ABSTRACT

A driving device for a switching element including a control terminal, the driving device includes at least one of a turn-on processing circuit or a turn-off processing circuit and switches the switching element on and off by generating a driving signal based on a control signal that switches between a low level and a high level. The turn-on processing circuit performs a turn-on processing of, at turn-on, storing an on-delay time and setting a period of time when the driving signal is at a low level within a period of time when the control signal is at the high level. The turn-off processing circuit performs a turn-off processing of, at turn-off, storing an off-delay time and setting a period of time when the driving signal is at a high level within a period of time when the control signal is at the low level.

### CROSS-REFERENCE TO RELATED APPLICATION

This application claims priority to Japanese Patent Application No. 2024-098898 filed on Jun. 19, 2024, the entire disclosure of which is incorporated herein by reference.

### BACKGROUND ART

The present disclosure relates to a driving device for a switching element.

A driving device described in Japanese Patent Application Publication No. 2022-067980 drives a switching element. The switching element includes a control terminal, a first terminal, and a second terminal. When a voltage is applied to the control terminal, a current flows between the first terminal and second terminal.

The driving device includes an active driving unit and a driving control unit. The active driving unit includes two series connection bodies in each of which a switch and a resistor are connected in series. The resistors of the two series connection bodies have different resistances from each other. When the switches of the two series connection bodies are alternately switched on and off, the resistors to be connected to the control terminal of the switching element are switched. This varies a voltage that is applied to the control terminal of the switching element.

At turn-off of the switching element, the driving control unit controls the switches so that the resistors to be connected to the control terminal are switched when a voltage between the first terminal and the second terminal reaches a predetermined value. This suppresses voltage surge. Such active control in which a gate voltage is controlled during switching transition has been proposed.

A time delay occurs from a point of time when a driving signal is input to the control terminal of the switching element to a point of time when the switching element is actually turned on. The same goes for turning the switching element off.

This time delay fluctuates depending on a load voltage, a load current, a temperature, and variations in element itself. Thus, in the active control, feedback control in which a start of operation of the switching element is detected, and then, the gate voltage is controlled is desirable. However, when a switching speed of the switching element such as a silicon carbide (SiC) semiconductor and a gallium nitride (GaN) semiconductor, which have been put into practical use in recent years, is fast, the feedback is not provided until the next switching transition, so that the voltage surge may not be suppressed.

### SUMMARY

In accordance with an aspect of the present disclosure, there is provided a driving device for a switching element including a first terminal, a second terminal, and a control terminal, the driving device including at least one of a turn-on processing circuit or a turn-off processing circuit. The driving device switches the switching element on and off by generating a driving signal based on a control signal that switches between a low level and a high level and by outputting the driving signal to the control terminal. The turn-on processing circuit performs a turn-on processing of, at turn-on of the switching element, storing an on-delay time from a rising edge of the control signal to a start of a drop of a voltage between the first terminal and the second terminal and setting a period of time when the driving signal is at a low level within a period of time when the control signal is at the high level based on the on-delay time at a previous turn-on. The turn-off processing circuit performs a turn-off processing of, at turn-off of the switching element, storing an off-delay time from a falling edge of the control signal to a start of a rise of the voltage between the first terminal and the second terminal and setting a period of time when the driving signal is at a high level within a period of time when the control signal is at the low level based on the off-delay time at a previous turn-off.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The disclosure, together with objects and advantages thereof, may best be understood by reference to the following description of the embodiments together with the accompanying drawings in which:

FIG. 1 is a configuration diagram of a driving device for a switching element; and

FIG. 2 is a timing diagram illustrating a relationship between time and voltage.

### DETAILED DESCRIPTION OF THE EMBODIMENTS

The following will describe an embodiment of a driving device for a switching element according to the present disclosure.

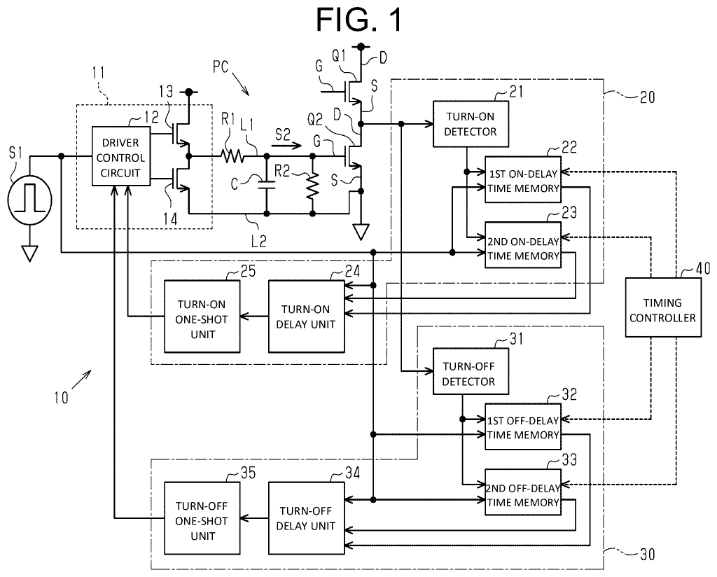

As illustrated in FIG. 1, a power converter PC includes a switching element Q1 as a high-side switch and a switching element Q2 as a low-side switch. A load, which is not illustrated, is connected to a node between the switching element Q1 and the switching element Q2. The power converter PC performs power conversion of an input voltage and supplies an output voltage to the load. The switching elements Q1, Q2 are, for example, metal oxide semiconductor field effect transistors (MOSFETs). The switching elements Q1, Q2 may be made of a semiconductor material such as silicon carbide (SiC) and gallium nitride (GaN). The switching element Q2 includes a gate G, a drain D, and a source S. The gate G is an example of a control terminal in the present disclosure. The drain D is an example of the first terminal in the present disclosure. The source S is an example of the second terminal in the present disclosure. The switching elements Q1, Q2 may be switching elements such as insulated gate bipolar transistors, other than MOSFETs.

The power converter PC includes a driving device 10 for a switching element. The driving device 10 for the switching element switches the switching elements Q1, Q2 on and off. As an example, the following will describe the driving device 10 for the switching element, which is provided for the switching element Q2; however, the same driving device 10 for the switching element is provided also for the switching element Q1.

The driving device 10 for the switching element includes a driver 11. The driver 11 has, for example, a driver control circuit 12 and two transistors 13, 14 connected in series to each other. A terminal of the transistor 13, which is different from a terminal connected to the transistor 14, is connected to a control power supply. A control signal S1 is input to the driver control circuit 12. The control signal S1 is, for example, a signal that is determined by comparing a voltage command and a carrier signal. The control signal S1 is output from an IC, for example. The control signal S1 is a pulse signal that switches between a low level and a high level. At a rising edge of the control signal S1, the control signal S1 is transitioned from the low level to the high level. At a falling edge of the control signal S1, the control signal S1 is transitioned from the high level to the low level.

The driver 11 generates a driving signal S2 based on the control signal S1 and outputs the driving signal S2 to the gate G of the switching element Q2. The driving signal S2 is a signal for switching the switching element Q2 on and off. The driving signal S2 is a pulse signal that switches between a low level and a high level. At a rising edge of the driving signal S2, the driving signal S2 is transitioned from the low level to the high level. At a falling edge of the driving signal S2, the driving signal S2 is transitioned form the high level to the low level.

The driver control circuit 12 controls transistors 13, 14 according to the control signal S1 and an output from a turn-on one-shot unit 25 or a turn-off one-shot unit 35, which will be described later. When the transistor 13 is turned on and the transistor 14 is turned off, the driving signal S2 at the high level is output from the driver 11. Thus, the switching element Q2 is turned on by a voltage from the control supply power. When the transistor 13 is turned off and the transistor 14 is turned on, the driving signal S2 at the low level is output from the driver 11. Thus, a voltage at the gate G drops to a voltage at the source S through a second connection line L2, which will be described later, so that the switching element Q2 is turned off. The switching element Q2 is turned on when the driving signal S2 goes to the high level and is turned off when the driving signal S2 goes to the low level.

The driving device 10 for the switching element includes a first connection line L1 that connects a node between the two transistors 13, 14 to the gate G and the second connection line L2 that connects the transistor 14 to the source S. The driving signal S2 is input to the gate G through the first connection line L1. The second connection line L2 connects the source S to a terminal of the transistor 14, which is different from a terminal connected to the transistor 13.

The driving device 10 for the switching element includes a gate resistor R1, a resistor R2, and a capacitor C. The gate resistor R1 is provided on the first connection line L1. The resistor R2 and the capacitor C are provided between the gate resistor R1 and the gate G and one terminal of each of the resistor R2 and the capacitor C is connected to the first connection line L1 and the other terminal is connected to the second connection line L2.

### <Turn-on Processing Circuit>

The driving device 10 for the switching element includes a turn-on processing circuit 20. The turn-on processing circuit 20 performs a turn-on processing. The turn-on processing is a process in which active control is performed when the switching element Q2 is turned on. The active control is a control for suppressing voltage surge by switching the driving signal S2 between the low level and the high level. In the active control at the turn-on, a period of time when the driving signal S2 is at the low level is set within a period of time when the control signal S1 is at the high level.

The turn-on processing circuit 20 includes a turn-on detector 21 that detects that the switching element Q2 is turned on. The turn-on detector 21 detects that the switching element Q2 is turned on by comparing a drain-to-source voltage Vds with an on-threshold value. When the driving signal S2 goes to the high level, a gate-to-source voltage Vgs increases. When the gate-to-source voltage Vgs becomes a predetermined value or more, the switching element Q2 is turned on. When the switching element Q2 is turned on, the drain-to-source voltage Vds decreases. Thus, the turn-on detector 21 may detect that the switching element Q2 is turned on by determining whether the drain-to-source voltage Vds is less than the on-threshold value or not.

The on-threshold value is the predetermined value. The on-threshold value is determined so that a start of a drop of the drain-to-source voltage Vds is detectable. The start of the drop of the drain-to-source voltage Vds refers to a specific point in a period of time from when the drain-to-source voltage Vds starts to drop actually to before the drain-to-source voltage Vds drops completely. When the on-threshold value is set in this way, the turn-on detector 21 detects the start of the drop of the drain-to-source voltage Vds. The drain-to-source voltage Vds is an example of the voltage between the first terminal and the second terminal in the present disclosure.

The turn-on detector 21 has, for example, a comparator. The drain-to-source voltage Vds and the on-threshold value are input to the comparator. The comparator, when the drain-to-source voltage Vds is equal to or more than the on-threshold value, outputs a signal at a low level. The comparator, when the drain-to-source voltage Vds is less than the on-threshold value, outputs a signal at a high level. At a rising edge of an output of the turn-on detector 21, the output of the turn-on detector 21 is transitioned from the low level to the high level.

The turn-on processing circuit 20 includes a first on-delay time memory 22 and a second on-delay time memory 23 as the on-delay time memory. The control signal S1 and the output of the turn-on detector 21 are input to the first on-delay time memory 22 and the second on-delay time memory 23. The first on-delay time memory 22 and the second on-delay time memory 23 store a period of time from the rising edge of the control signal S1 to the rising edge of the output of the turn-on detector 21 as the on-delay time of the switching element Q2. The switching element Q2 has a transition period from the rising edge of the driving signal S2 following the rising edge of the control signal S1 to the rising edge of the output of the turn-on detector 21 following the point of time when the drain-to-source voltage Vds reaches less than the on-threshold value. This transition period is the on-delay time.

The first on-delay time memory 22 and the second on-delay time memory 23 are, for example, each formed of an integrating circuit using a capacitor. While a constant current flows into the capacitor for the period of time from the rising edge of the control signal S1 to the rising edge of the output of the turn-on detector 21, the capacitor stores electric charges corresponding to the on-delay time. As a result, the first on-delay time memory 22 and the second on-delay time memory 23 store the on-delay time as a voltage across the capacitor.

The turn-on processing circuit 20 includes a turn-on delay unit 24. The turn-on delay unit 24 receives the control signal S1 and reads the on-delay time from one of the first on-delay time memory 22 and the second on-delay time memory 23. For example, the turn-on delay unit 24 reads the on-delay time by generating a current corresponding to the voltage of each capacitor of the first on-delay time memory 22 and the second on-delay time memory 23. The turn-on delay unit 24 may correct the on-delay time read from the first on-delay time memory 22 or the second on-delay time memory 23 according to a propagation delay time from the start of the drop of the drain-to-source voltage Vds to the rising edge of the output of the turn-on detector 21. For example, the turn-on delay unit 24 may subtract the propagation delay time from the on-delay time read from the first on-delay time memory 22 or the second on-delay time memory 23 to correct the on-delay time. The propagation delay time only needs to be obtained in advance by an experiment or a simulation. The turn-on delay unit 24 outputs a point of time when the on-delay time has elapsed after the rising edge of the control signal S1.

The turn-on processing circuit 20 includes a turn-on one-shot unit 25. The turn-on one-shot unit 25 outputs a negative pulse to the driver control circuit 12 at the point of time output from the turn-on delay unit 24. The negative pulse intervenes with the control signal S1 to control the transistors 13, 14 so that the driving signal S2 output from the driver 11 is set to the low level. While the negative pulse is input to the driver control circuit 12 from the turn-on one-shot unit 25, even when the control signal S1 is at the high level, the driver control circuit 12 controls the transistors 13, 14 so that the driving signal S2 at the low level is output from the driver 11. Thus, the turn-on one-shot unit 25 sets a period of time when the driving signal S2 is at the low level within the period of time when the control signal S1 is at the high level. A width of the negative pulse may be constant or variable. In a case where the width of the negative pulse is set variable, for example, the width only needs to be changed according to a load condition.

The driving device 10 for the switching element includes a timing controller 40. The timing controller 40 controls the driving device 10 for the switching element. The timing controller 40, at the turn-on, stores the on-delay time in one of the first on-delay time memory 22 and the second on-delay time memory 23 and causes the turn-on delay unit 24 to read the on-delay time from the other of the first on-delay time memory 22 and the second on-delay time memory 23.

One control cycle is defined by a period of time from when the control signal S1 goes to the high level and is transitioned to the low level until the control signal S1 goes to the high level again. The timing controller 40 alternately switches between the first on-delay time memory 22 and the second on-delay time memory 23 so that one stores the on-delay time while the on-delay time is read into the turn-on delay unit 24 from the other. That is, at each turn-on, the timing controller 40 switches between the first on-delay time memory 22 and the second on-delay time memory 23 to store the on-delay time therein. As a result, at each turn-on, the timing controller 40 switches between the first on-delay time memory 22 and the second on-delay time memory 23 from which the on-delay time is read into the turn-on delay unit 24.

During a control cycle in which the timing controller 40 stores the on-delay time in the first on-delay time memory 22, the on-delay time is read into the turn-on delay unit 24 from the second on-delay time memory 23. During a control cycle in which the timing controller 40 stores the on-delay time in the second on-delay time memory 23, the on-delay time is read into the turn-on delay unit 24 from the first on-delay time memory 22. Thus, at the turn-on, the on-delay time stored in the first on-delay time memory 22 or the second on-delay time memory 23 at a previous turn-on is read into the turn-on delay unit 24. Accordingly, the point of time when the turn-on one-shot unit 25 outputs the negative pulse is set based on the on-delay time at the previous turn-on of the switching element Q2. Note that the turn-on detector 21, the first on-delay time memory 22, and the second on-delay time memory 23 may be reset, for example, after a predetermined time has elapsed or by a predetermined signal such as the control signal S1 and the driving signal S2.

As described above, the turn-on processing is the process in which at the turn-on of the switching element Q2, the on-delay time is stored and the period of time when the driving signal S2 is at the low level is set within the period of time when the control signal S1 is at the high level based on the on-delay time at the previous turn-on of the switching element Q2.

### <Turn-Off Processing Circuit>

The driving device 10 for the switching element includes a turn-off processing circuit 30. The turn-off processing circuit 30 performs a turn-off processing. The turn-off processing is a process in which active control is performed when the switching element Q2 is turned off. In the active control at the turning off, a period of time when the driving signal S2 is at the high level is set within a period of time when the control signal S1 is at the low level.

The turn-off processing circuit 30 includes a turn-off detector 31 that detects that the switching element Q2 is turned off. The turn-off detector 31 detects that the switching element Q2 is turned off by comparing the drain-to-source voltage Vds with an off-threshold value. When the driving signal S2 goes to the low level, the gate-to-source voltage Vgs decreases. When the gate-to-source voltage Vgs becomes less than a predetermined value, the switching element Q2 is turned off. When the switching element Q2 is turned off, the drain-to-source voltage Vds increases. Thus, the turn-off detector 31 may detect that the switching element Q2 is turned off by determining whether the drain-to-source voltage Vds is equal to or more than the off-threshold value or not.

The off-threshold value is the predetermined value. The off-threshold value is determined so that a start of a rise of the drain-to-source voltage Vds is detectable. The start of the rise of the drain-to-source voltage Vds refers to a specific point in a period of time from when the drain-to-source voltage Vds starts to rise actually to before the drain-to-source voltage Vds rises completely. When the off-threshold value is set in this way, the turn-off detector 31 detects the start of the rise of the drain-to-source voltage Vds.

The turn-off detector 31 has, for example, a comparator. The drain-to-source voltage Vds and the off-threshold value are input to the comparator. The comparator, when the drain-to-source voltage Vds is equal to or more than the off-threshold value, outputs a signal at a high level. The comparator, when the drain-to-source voltage Vds is less than the off-threshold value, outputs a signal at a low level. At a rising edge of the output of the turn-off detector 31, the output of the turn-off detector 31 is transitioned from the low level to the high level.

The turn-off processing circuit 30 includes a first off-delay time memory 32 and a second off-delay time memory 33 as the off-delay time memory. The control signal S1 and the output of the turn-off detector 31 are input to the first off-delay time memory 32 and the second off-delay time memory 33. The first off-delay time memory 32 and the second off-delay time memory 33 store a period of time from the falling edge of the control signal S1 to the rising edge of the output of the turn-off detector 31 as the off-delay time of the switching element Q2. The switching element Q2 has a transition period from the falling edge of the driving signal S2 following the falling edge of the control signal S1 to the rising edge of the output of the turn-off detector 31 following the point of time when the drain-to-source voltage Vds reaches the off-threshold value or more. This transition period is the off-delay time.

The first off-delay time memory 32 and the second off-delay time memory 33 are, for example, each formed of an integrating circuit using a capacitor. While a constant current flows into the capacitor for the period of time from the falling edge of the control signal S1 to the rising edge of the output of the turn-off detector 31, the capacitor stores electric charges corresponding to the off-delay time. As a result, the first off-delay time memory 32 and the second off-delay time memory 33 store the off-delay time as a voltage across the capacitor.

The turn-off processing circuit 30 includes a turn-off delay unit 34. The turn-off delay unit 34 receives the control signal S1 and reads the off-delay time from one of the first off-delay time memory 32 and the second off-delay time memory 33. For example, the turn-off delay unit 34 reads the off-delay time by generating a current corresponding to the voltage of each capacitor of the first off-delay time memory 32 and the second off-delay time memory 33. The turn-off delay unit 34 may correct the off-delay time read from the first off-delay time memory 32 or the second off-delay time memory 33 according to a propagation delay time from the start of the rise of the drain-to-source voltage Vds to the rising edge of the output of the turn-off detector 31. For example, the turn-off delay unit 34 may subtract the propagation delay time from the off-delay time read from the first off-delay time memory 32 or the second off-delay time memory 33 to correct the off-delay time. The propagation delay time only needs to be obtained in advance by an experiment or a simulation. The turn-off delay unit 34 outputs a point of time when the off-delay time has elapsed after the falling edge of the control signal S1.

The turn-off processing circuit 30 includes a turn-off one-shot unit 35. The turn-off one-shot unit 35 outputs a positive pulse to the driver control circuit 12 at the point of time output from the turn-off delay unit 34. The positive pulse intervenes with the control signal S1 to control the transistors 13, 14 so that the driving signal S2 output from the driver 11 is set to the high level. While the positive pulse is input to the driver control circuit 12 from the turn-off one-shot unit 35, even when the control signal S1 is at the low level, the driver control circuit 12 controls the transistors 13, 14 so that the driving signal S2 at the high level is output from the driver 11. Thus, the turn-off one-shot unit 35 sets a period of time when the driving signal S2 is at the high level within the period of time when the control signal S1 is at the low level. A width of the positive pulse may be constant or variable. In a case where the width of the positive pulse is set variable, for example, the width only needs to be changed according to a load condition.

The timing controller 40, at the turn-off, stores the off-delay time in one of the first off-delay time memory 32 and the second off-delay time memory 33 and causes the turn-off delay unit 34 to read the off-delay time from the other of the first off-delay time memory 32 and the second off-delay time memory 33.

The timing controller 40 alternately switches between the first off-delay time memory 32 and the second off-delay time memory 33 so that one stores the off-delay time while the off-delay time is read into the turn-off delay unit 34 from the other. That is, at each turn-off, the timing controller 40 switches between the first off-delay time memory 32 and the second off-delay time memory 33 to store the off-delay time therein. As a result, at each turn-off, the timing controller 40 switches between the first off-delay time memory 32 and the second off-delay time memory 33 from which the off-delay time is read into the turn-off delay unit 34

During a control cycle in which the timing controller 40 stores the off-delay time in the first off-delay time memory 32, the off-delay time is read into the turn-off delay unit 34 from the second off-delay time memory 33. During a control cycle in which the timing controller 40 stores the off-delay time in the second off-delay time memory 33, the off-delay time is read into the turn-off delay unit 34 from the first off-delay time memory 32. Thus, at the turn-off, the off-delay time stored in the first off-delay time memory 32 or the second off-delay time memory 33 at a previous turn-off is read into the turn-off delay unit 34. Accordingly, the point of time when the turn-off one-shot unit 35 outputs the positive pulse is set based on the off-delay time at the previous turn-off of the switching element Q2. Note that the turn-off detector 31, the first off-delay time memory 32, and the second off-delay time memory 33 may be reset, for example, after a predetermined time has elapsed or by a predetermined signal such as the control signal S1 and the driving signal S2.

As described above, the turn-off processing is the process in which at the tuning-off of the switching element Q2, the off-delay time is stored and the period of time when the driving signal S2 is at the high level is set within the period of time when the control signal S1 is at the low level based on the off-delay time at the previous turn-off of the switching element Q2.

### Operation of the Present Embodiment

The following will describe operation of the present embodiment. As an example, the following will describe a case where the active control is not performed in the first control cycle but is performed in the second and subsequent control cycles.

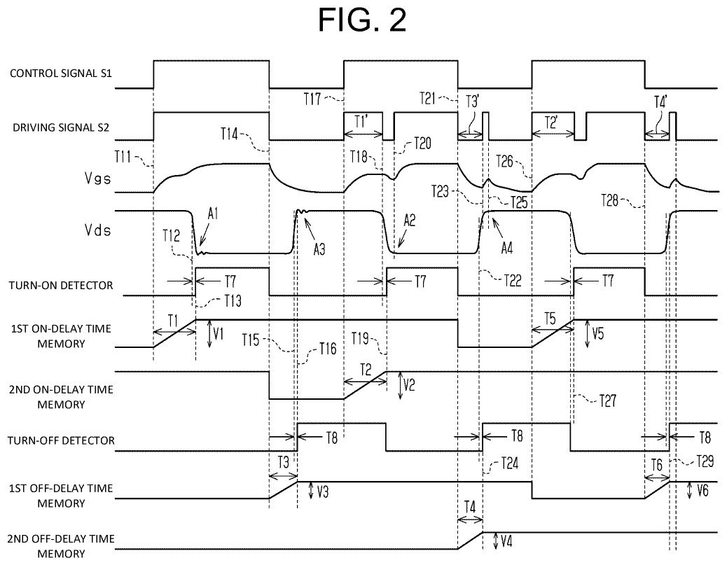

As illustrated in FIG. 2, when the first control cycle starts at a time T11, the control signal S1 goes to the high level. Then, when the driving signal S2 goes to the high level following the control signal S1, the gate-to-source voltage Vgs increases. When the drain-to-source voltage Vds reaches the on-threshold value at a time T12, the output of the turn-on detector 21 goes to the high level at a time T13. The first on-delay time memory 22 stores an on-delay time T1 from the time T11 to the time T13 as a capacitor voltage V1 in its integrating circuit. A period of time from the time T12 to the time T13 corresponds to a propagation delay time T7 of the turn-on detector 21. The propagation delay time T7 is a time from the start of the drop of the drain-to-source voltage Vds to the rising edge of the output of the turn-on detector 21.

When the control signal S1 goes to the low level at a time T14, the driving signal S2 goes to the low level. As a result, the gate-to-source voltage Vgs decreases. When the drain-to-source voltage Vds reaches the off-threshold value at a time T15, the output of the turn-off detector 31 goes to the high level at a time T16. The first off-delay time memory 32 stores an off-delay time T3 from the time T14 to the time T16 as a capacitor voltage V3 in its integrating circuit. A period of time from the time T15 to the time T16 corresponds to a propagation delay time T8 of the turn-off detector 31. The propagation delay time T8 is a time from the start of the rise of the drain-to-source voltage Vds to the rising edge of the output of the turn-off detector 31.

When the second control cycle starts at a time T17, the control signal S1 goes to the high level. Then, when the driving signal S2 goes to the high level following the control signal S1, the gate-to-source voltage Vgs increases. The turn-on delay unit 24 reads the on-delay time T1 stored in the first on-delay time memory 22 in the first control cycle. The on-delay time T1 is the on-delay time at the previous turn-on. The turn-on one-shot unit 25 outputs the negative pulse to the driver 11 at a time T18 after an on-delay time T1′ has elapsed since the time T17. This allows the period of time when the driving signal S2 is at the low level to be set within the period of time when the control signal S1 is at the high level. The driving signal S2 is kept at the low level from the time T18 to a time T20. The on-delay time T1′ may be equal to the on-delay time T1, and may be a time obtained by subtracting the propagation delay time T7 from the on-delay time T1.

The time T18 coincides with a point of time when the drain-to-source voltage Vds reaches the on-threshold value. This is because the load condition fluctuates little in two successive control cycles, so that a period of time when the control signal S1 is kept at the high level is the same or substantially the same. Accordingly, a point of time when the drain-to-source voltage Vds reaches the on-threshold value at the current turn-on is estimated based on the on-delay time T1 at the previous turn-on. Then, at the point of time, the driving signal S2 is set to the low level.

The output of the turn-on detector 21 goes to the high level at a time T19. The second on-delay time memory 23 stores an on-delay time T2 from the time T17 to the time T19 as a capacitor voltage V2 in its integrating circuit.

When the control signal S1 goes to the low level at a time T21, the driving signal S2 goes to the low level. As a result, the gate-to-source voltage Vgs decreases. The turn-off delay unit 34 reads the off-delay time T3 stored in the first off-delay time memory 32 in the first control cycle. The off-delay time T3 is the off-delay time at the previous turn-off. The turn-off one-shot unit 35 outputs the positive pulse to the driver 11 at a time T23 after an off-delay time T3′ has elapsed since the time T21. This allows the period of time when the driving signal S2 is at the high level to be set within the period of time when the control signal S1 is at the low level. The driving signal S2 is kept at the high level from the time T23 to a time T25. The off-delay time T3′ may be equal to the off-delay time T3, and may be a time obtained by subtracting the propagation delay time T8 from the off-delay time T3.

The time T23 is little different from a time T22 when the drain-to-source voltage Vds reaches the off-threshold value. Thus, although there is a case where the time T23 when the driving signal S2 goes to the high level does not coincide with the time T22, as compared with a case where the driving signal S2 is set to the high level after the turn-off detector 31 detects that the switching element Q2 is turned off, a period of time from when the drain-to-source voltage Vds reaches to the off-threshold value until the driving signal S2 goes to the high level is shortened.

The output of the turn-off detector 31 goes to the high level at a time T24. The second off-delay time memory 33 stores an off-delay time T4 from the time T21 to the time T24 as a capacitor voltage V4 in its integrating circuit.

The same control as that in the second control cycle is performed in the third control cycle. A period of time when the driving signal S2 is at the low level is set within the period of time when the control signal S1 is at the high level, at the third turn-on. The driving signal S2 goes to the low level after the on-delay time T2′ has elapsed since a time T26 at the rising edge of the control signal S1. The on-delay time T2′ may be equal to the on-delay time T2, and may be a time obtained by subtracting the propagation delay time T7 from the on-delay time T2. The on-delay time T2 is the on-delay time in the second control cycle, that is, at the previous turn-on.

The output of the turn-on detector 21 goes to the high level at a time T27. The first on-delay time memory 22 stores an on-delay time T5 from the time T26 to the time T27 as a capacitor voltage V5 in its integrating circuit. This on-delay time T5 is used at the next turn-on.

A period of time when the driving signal S2 is at the high level is set within the period of time when the control signal S1 is at the low level, at the third turn-off. The driving signal S2 goes to the high level after an off-delay time T4′ has elapsed since a time T28 at the falling edge of the control signal S1. The off-delay time T4′ may be equal to the off-delay time T4, and may be a time obtained by subtracting the propagation delay time T8 from the off-delay time T4. The off-delay time T4 is the off-delay time in the second control cycle, that is, at the previous turn-off.

The output of the turn-off detector 31 goes to the high level at a time T29. The first off-delay time memory 32 stores an off-delay time T6 from the time T28 to the time T29 as a capacitor voltage V6 in its integrating circuit. This on-delay time T6 is used at the next turn-on.

### Advantageous Effect of the Present Embodiment

(1) The driving device 10 for the switching element performs the turn-on processing. In the turn-on processing, the period of time when the driving signal S2 is at the low level is set within the period of time when the control signal S1 is at the high level based on the on-delay time. The period of time when the driving signal S2 is at the low level is set using the on-delay time at the previous turn-on, so that the driving signal S2 does not need to be set to the low level just after the switching element Q2 is detected to be turned on. Since the load condition fluctuates little in the subsequent control cycles, the period of time when the control signal S1 is kept at the high level is the same or substantially the same. Thus, the on-delay time at the previous turn-on and the on-delay time at the current turn-on are regarded as the same. The period of time when the driving signal S2 is at the low level may be set using the on-delay time at the previous turn-on. Thus, the voltage surge is suppressed regardless of a switching speed of the switching element Q2. Here, the voltage surge includes ringing and overshoot of the drain-to-source voltage Vds.

For example, as illustrated by a reference sign A1 in FIG. 2, the active control is not performed in the first control cycle, so that voltage surge occurs in the drain-to-source voltage Vds at the turn-on. In contrast, the increase in the gate-to-source voltage Vgs is temporarily suppressed in the second control cycle in which the active control is performed, so that as illustrated by a reference sign A2, the occurrence of voltage surge in the drain-to-source voltage Vds is suppressed.

In addition, the on-delay time is the period of time from the rising edge of the control signal S1 to the start of the drop of the drain-to-source voltage Vds. After the drain-to-source voltage Vds drops, the voltage surge may occur. Thus, in a case where the on-delay time is defined as a period of time from the rising edge of the control signal S1 until when the drain-to-source voltage Vds completely drops, the voltage surge may not be suppressed. On the contrary, the voltage surge is suppressed by defining the on-delay time as the period of time from the rising edge of the control signal S1 to the start of the drop of the drain-to-source voltage Vds.

(2) The driving device 10 for the switching element performs the turn-off processing. In the turn-off processing, the period of time when the driving signal S2 is at the high level is set within the period of time when the control signal S1 is at the low level based on the off-delay time. The period of time when the driving signal S2 is at the high level is set using the off-delay time at the previous turn-off, so that the driving signal S2 does not need to be set to the high level just after the switching element Q2 is detected to be turned off. Since the load condition fluctuates little in the subsequent control cycles, the period of time when the control signal S1 is kept at the high level is the same or substantially the same. Thus, the off-delay time at the previous turn-off and the off-delay time at the current turn-off are regarded as the same. The period of time when the driving signal S2 is at the high level may be set using the off-delay time at the previous turn-off. Thus, the voltage surge is suppressed regardless of a switching speed of the switching element Q2.

For example, as illustrated by a reference sign A3 in FIG. 2, the active control is not performed in the first control cycle, so that voltage surge occurs in the drain-to-source voltage Vds at the turn-off. In contrast, the decrease in the gate-to-source voltage Vgs is temporarily suppressed in the second control cycle in which the active control is performed, so that as illustrated by a reference sign A4, the occurrence of voltage surge in the drain-to-source voltage Vds is suppressed.

In addition, the off-delay time is the period of time from the falling edge of the control signal S1 to the start of the rise of the drain-to-source voltage Vds. After the drain-to-source voltage Vds rises, the voltage surge may occur. Thus, in a case where the off-delay time is defined as a period of time from the falling edge of the control signal S1 until the drain-to-source voltage Vds completely rises, the voltage surge may not be suppressed. On the contrary, the voltage surge is suppressed by defining the off-delay time as the period of time from the falling edge of the control signal S1 to the start of the rise of the drain-to-source voltage Vds.

(3) The timing controller 40 stores the on-delay time in one of the first on-delay time memory 22 and the second on-delay time memory 23 and causes the turn-on delay unit 24 to read the on-delay time from the other of the first on-delay time memory 22 and the second on-delay time memory 23. In addition, at each turn-on, the timing controller 40 alternately switches between the first on-delay time memory 22 and the second on-delay time memory 23 to store the on-delay time therein. This allows, at the turn-on, the on-delay time at the current turn-on to be stored in one of the first on-delay time memory 22 and the second on-delay time memory 23 and the period of time when the driving signal S2 is at the low level to be set based on the on-delay time at the previous turn-on.

(4) The turn-on delay unit 24 corrects the on-delay time read from the first on-delay time memory 22 or the second on-delay time memory 23 according to the propagation delay time of the turn-on detector 21. There is a delay from the start of the drop of the drain-to-source voltage Vds until the turn-on detector 21 detects the start of the drop of the drain-to-source voltage Vds. The driving signal S2 may be set to the low level at an appropriate time by correcting the on-delay time according to the propagation delay time due to this delay.

(5) The timing controller 40, at the turn-off, stores the off-delay time in one of the first off-delay time memory 32 and the second off-delay time memory 33 and causes the turn-off delay unit 34 to read the off-delay time from the other of the first off-delay time memory 32 and the second off-delay time memory 33. In addition, at each turn-off, the timing controller 40 alternately switches between the first off-delay time memory 32 and the second off-delay time memory 33 to store the off-delay time therein. This allows, at the turn-off, the off-delay time at the current turn-off to be stored in one of the first off-delay time memory 32 and the second off-delay time memory 33 and the period of time when the driving signal S2 is at the high level to be set based on the off-delay time at the previous turn-off.

(6) The turn-off delay unit 34 corrects the off-delay time read from the first off-delay time memory 32 or the second off-delay time memory 33 according to the propagation delay time of the turn-off detector 31. There is a delay from the start of the rise of the drain-to-source voltage Vds until the turn-off detector 31 detects the start of the rise of the drain-to-source voltage Vds. The driving signal S2 may be set to be the high level at an appropriate time by correcting the off-delay time according to the propagation delay time due to this delay.

(7) At the turn-on of the switching element Q2, the period of time when the driving signal S2 is at the low level is set within the period of time when the control signal S1 is at the high level. Furthermore, at the turn-off of the switching element Q2, the period of time when the driving signal S2 is at the high level is set within the period of time when the control signal S1 is at the low level. Accordingly, as compared with a configuration in which the gate resistances are switched, it is not necessary to provide a plurality of gate resistors nor a switch for switching between the gate resistances.

### Modification

The embodiment may be modified as follows. The embodiment and the following modifications may be combined with each other as long as they do not contradict each other technically.

The driving device 10 for the switching element only needs to perform at least one of the turn-on processing and the turn-off processing. When the driving device 10 for the switching element performs only the turn-on processing, the driving device 10 for the switching element need not include the turn-off processing circuit 30. When the driving device 10 for the switching element performs only the turn-off processing, the driving device 10 for the switching element need not include the turn-on processing circuit 20.

The first on-delay time memory 22 and the second on-delay time memory 23 may have any configuration as long as they store the on-delay time. For example, each of the first on-delay time memory 22 and the second on-delay time memory 23 may be formed of a digital circuit using a counter. Similarly, the first off-delay time memory 32 and the second off-delay time memory 33 may have any configuration as long as they store the off-delay time.

### Definition

The wording “at least one” used in the present specification means “one or more” of desired options. As an example, the wording “at least one” used in the present specification means “only one option” or “both two options” when the number of options is two. As another example, the wording “at least one” used in the present specification means “only one option” or “any combination of two or more options” when the number of options is three or more.

What is claimed is:

1. A driving device for a switching element including a first terminal, a second terminal, and a control terminal, the driving device comprising
at least one of a turn-on processing circuit or a turn-off processing circuit, and
the driving device switching the switching element on and off by generating a driving signal based on a control signal that switches between a low level and a high level and by outputting the driving signal to the control terminal, wherein
the turn-on processing circuit performs a turn-on processing of, at turn-on of the switching element, storing an on-delay time from a rising edge of the control signal to a start of a drop of a voltage between the first terminal and the second terminal and setting a period of time when the driving signal is at a low level within a period of time when the control signal is at the high level based on the on-delay time at a previous turn-on, and
the turn-off processing circuit performs a turn-off processing of, at turn-off of the switching element, storing an off-delay time from a falling edge of the control signal to a start of a rise of the voltage between the first terminal and the second terminal and setting a period of time when the driving signal is at a high level within a period of time when the control signal is at the low level based on the off-delay time at a previous turn-off.

2. The driving device for the switching element according to claim 1, further comprising
a timing controller, wherein
the driving device includes the turn-on processing circuit,
the turn-on processing circuit includes:
a turn-on detector that detects the start of the drop of the voltage between the first terminal and the second terminal;
an on-delay time memory that stores the on-delay time;
a turn-on delay unit that reads the on-delay time from the on-delay time memory; and
a turn-on one-shot unit that sets the period of time when the driving signal is at the low level within the period of time when the control signal is at the high level,
the on-delay time memory includes a first on-delay time memory and a second on-delay time memory,
the timing controller, at the turn-on, stores the on-delay time in one of the first on-delay time memory and the second on-delay time memory and causes the turn-on delay unit to read the on-delay time from the other of the first on-delay time memory and the second on-delay time memory, and
the timing controller switches between the first on-delay time memory and the second on-delay time memory to store the on-delay time each time the turn-on is performed.

3. The driving device for the switching element according to claim 2, wherein
the turn-on delay unit corrects the on-delay time read from the on-delay time memory according to a propagation delay time from the start of the drop of the voltage between the first terminal and the second terminal to a rising edge of an output of the turn-on detector.

4. The driving device for the switching element according to claim 1, further comprising
a timing controller, wherein
the driving device includes the turn-off processing circuit,
the turn-off processing circuit includes:
a turn-off detector that detects the start of the rise of the voltage between the first terminal and the second terminal;
an off-delay time memory that stores the off-delay time;
a turn-off delay unit that reads the off-delay time from the off-delay time memory; and
a turn-off one-shot unit that sets the period of time when the driving signal is at the high level within the period of time when the control signal is at the low level,
the off-delay time memory includes a first off-delay time memory and a second off-delay time memory,
the timing controller, at the turn-off, stores the off-delay time in one of the first off-delay time memory and the second off-delay time memory and causes the turn-off delay unit to read the off-delay time from the other of the first off-delay time memory and the second off-delay time memory, and
the timing controller switches between the first off-delay time memory and the second off-delay time memory to store the off-delay time each time the turn-off is performed.

5. The driving device for the switching element according to claim 4, wherein
the turn-off delay unit corrects the off-delay time read from the off-delay time memory according to a propagation delay time from the start of the rise of the voltage between the first terminal and the second terminal to a rising edge of an output of the turn-off detector.
